(19) United States
(12) Patent Application Publication
(10) Pub. No.: US 2004/0189188 A1
(43) Pub. Date: Sep. 30, 2004

(54) Active matrix organic electroluminescent panel

(75) Inventors: Ching-Lin Fan, Hukou Township (TW); Tien Wang Huang, Hukou Township (TW); Mei-Ying Chang, Hukou Township (TW)

Correspondence Address: BACON & THOMAS, PLLC, 625 SLATERS LANE, FOURTH FLOOR, ALEXANDRIA, VA, 22314

(73) Assignee: RiTdisplay Corporation, Hukou Township (TW)

(21) Appl. No.: 10/743,876

(22) Filed: Dec. 24, 2003

(30) Foreign Application Priority Data
Dec. 24, 2002 (TW) 091137160

(51) Int. Cl. H01J 1/62

(52) U.S. Cl. 313/504

(57) ABSTRACT

An active matrix organic electroluminescent panel is disclosed, which comprises a substrate; a plurality of functional elements, which having at least one transistor having a drain, a source, and a gate; a plurality of organic electroluminescent devices disposed over the substrate, which comprised, in sequence, a first electrode, at least one organic electroluminescent media and a second electrode; and a plurality of conductive lines disposed over the surface of the substrate to connect the and/or organic electroluminescent devices; wherein the conductive lines comprises silver-copper alloy, which is composed of 80 to 99.8 mol % of silver, 0.1 to 10 mol % of copper, and 0.1 to 10 mol % of transition metal selected from the group consisting of palladium, magnesium, gold, platinum, and the combinations thereof, and the total mol % of the silver-copper alloy is 100.

### BACKGROUND OF THE INVENTION

1. Field of the Invention

The present invention relates to an electroluminescent panel and, more particularly, to an active matrix organic electroluminescent panel.

2. Description of Related Art

Since the introduction of modern computing, the display has become the most important interface between the user and the computer. Since the beginning of the 1990's, technological developments combined with market demands have resulted in constant upgrading of displays available to consumers. More recently, the flat panel display (FPD) has gradually replaced the traditional cathode ray tube (CRT) display and become the mainstream in the display marketplace owing to its low weight, compact size and attractive styling. Among the flat panel displays, the organic electroluminescent panel is a particularly favored new generation display due to its advantages of lightweight, high contrast, fast response time, low power consumption, and high brightness, etc.

The organic electroluminescent panel is a device that utilizes the organic functional materials, which radiate spontaneously to achieve image display. According to the molecular weight of the organic functional materials, the organic electroluminescent panel is classified into two types, i.e. the small molecule OLED (SM-OLED) and the polymer light-emitting device (PLED).

Generally, there are two methods to drive the organic electroluminescent panel, i.e. the passive driving and the active driving. The passive driving OLED has a short lifetime and high power consumption, and can only be applied to small size panels. However, the active driving OLED not only has a low power consumption and high reliability, but also is the main stream for application in large size panels in the future. For the development of large-sized panels, it is required to form conductive lines with a low resistance. The conductive lines with a low resistance will lower RC-delay and provide large size panels with improved aperture ratio, brightness, and uniformity, and reduced cost, etc.

Currently, the active driving FPD, such as the AMLCD, uses a transition metal, such as Mo, Cr, or Ta to form the conductive lines. In order to obtain good step-coverage, the thickness of the conductive line must be thin. However, the thin conductive line will cause an increase in resistance, which leads to a rise in RC-delay. Hence, the size of the panel that uses the transition metals will be limited. Therefore, there is a need to develop a process or a material for manufacturing a conductive line that has an extra low resistance in order to produce a large size FDP.

From the viewpoint of processing of the metal connecting line, the thicker and wider the metal line is, the lower the resistance will be. However, a thick metal line has the disadvantages of poor step-coverage and pinhole formation. Although the taper etching process can improve those disadvantages, the manufacturing cost of panels will increase. Moreover, the wide metal line will reduce the aperture ratio and produce the parasitic capacitance. Therefore, it is not feasible to form a thicker and wider metal line.

Recently, a planarization process of metal connecting lines has been proposed to improve the step-coverage and pinhole formation. However, the planarization process requires extra processing procedures and materials. Also, the planarization will cause an increase in parasitic capacitance. Thus, by improving the materials involved, the aforementioned disadvantages can be overcome. To meet the aforementioned requirements, aluminum is first developed because it has a low resistance and can be processed easily. However, a hillock defect often comes into existence in aluminum when the aluminum is under high temperature circumstance or has a high current running therein. The hillock defect will further cause the connecting line to be short or broken, which leads to a deficiency in reliability of the panel. As for copper, it is a better choice for the manufacturing of connecting conductive lines because it has an even lower resistance than aluminum. However, copper has a poor adhesion to the glass substrate, oxidizes easily at its surface, and is difficult to etch. Consequently, it is necessary to modify the process or to change the composition of the conductive line. As a result, there will be a substantial increase in the manufacturing cost, which does not meet the need in the mass production of the organic electroluminescent panel.

Therefore, it is desirable to provide an active matrix organic electroluminescent panel to mitigate and/or obviate the aforementioned problems.

### SUMMARY OF THE INVENTION

The present invention is to provide an active matrix organic electroluminescent panel so as to reduce the resistance of the conductive lines, to improve the adhesion of the conductive lines, to lower the reactivity of the conductive lines, to make the etching of the conductive lines easier, and to improve the reliability, aperture ratio, brightness, and uniformity of the organic electroluminescent panel.

The present invention is also to provide an active matrix organic electroluminescent panel so that taking advantage of the low resistance of silver leads to a reduction of the RC-delay.

The present invention is further to provide a method for manufacturing the active matrix organic electroluminescent panel so as to reduce the resistance of the conductive lines, to improve the adhesion of the conductive lines, to lower the reactivity of the conductive lines, to make the etching of the conductive lines easier, and to improve the reliability, aperture ratio, brightness, and uniformity of the organic electroluminescent panel.

The active matrix organic electroluminescent panel of the present invention comprises a substrate; a plurality of functional elements located over the substrate; a plurality of organic electroluminescent devices disposed over the substrate; wherein the organic electroluminescent device comprised, in sequence, a first electrode, at least one organic electroluminescent media and a second electrode; and a plurality of conductive lines disposed over the surface of the substrate to connect the organic electroluminescent devices; wherein the conductive lines comprise silver-copper alloy, which is composed of 80 to 99.8 mol % of silver, 0.1 to 10 mol % of copper, and 0.1 to 10 mol % of transition metal selected from the group consisting of palladium, magnesium, gold, platinum, and the combinations thereof, and the total mol % of the silver-copper alloy is 100.

The method for manufacturing an active matrix organic electroluminescent panel of the present invention comprises providing a substrate; forming a plurality of functional elements over the substrate, forming a plurality of organic electroluminescent devices over the substrate, wherein the organic electroluminescent device comprised, in sequence, a first electrode, at least one organic electroluminescent media and a second electrode; and forming a plurality of conductive lines over the surface of the substrate to connect the organic electroluminescent devices; wherein the conductive lines comprise silver-copper alloy, which is composed of 80 to 99.8 mol % of silver, 0.1 to 10 mol % of copper, and 0.1 to 10 mol % of a transition metal selected from the group consisting of palladium, magnesium, gold, platinum, and the combinations thereof, and the total mol % of the silver-copper alloy is 100.

The first electrode of the active matrix organic electroluminescent panel of the present invention incorporates with at least one functional element for driving the pixel electrode. Preferably, the first electrode incorporates with two functional elements, i.e. the switch transistor and the driving transistor, in order to drive the pixel electrode. It is optionally to form a buffer layer over the surface of the active matrix organic electroluminescent panel of the present invention. The material of the buffer layer can be any conventional buffer material. Preferably, the buffer layer is made of silicon nitride, silicon oxide, or silicon oxynitride. It is optionally to form at least one connecting conductive line to connect the functional elements that incorporate with the anode (the first electrode) of the pixel of the active matrix organic electroluminescent panel of the present invention. The connecting conductive line can be made of any conventional material. Preferably, the connecting conductive line and the conductive line are comprised silver-copper alloy.

The silver-copper alloy of the active matrix organic electroluminescent panel of the present invention optionally comprises an adhesion improver to improve the adhesion of the silver-copper alloy to the substrate. Preferably, the adhesion improver is 0.01 to 5 mol % of titanium, aluminum, nickel, cobalt, or chromium. The percentage of the adhesion improver of the present invention is not restricted. Preferably, the percentage of the adhesion improver ranges from 0.01 to 5 mol %. The substrate of the active matrix organic electroluminescent panel of the present invention can be any conventional substrate. Preferably, the substrate is a glass substrate, a plastic substrate, a flexible substrate, or a transparent resin plate. The material of the substrate can be any conventional material. Preferably, the material of the substrate is polycarbonate, polyethylene terephthalate (PET), cyclic olefin copolymer (COC), or metal-containing cyclic olefin copolymer (m-COC). The material of the second electrode (the cathode) of the present invention can be any conventional material for electrodes. Preferably, the material of the second electrode is a metal with a low resistance. More preferably, the material of the second electrode is aluminum, aluminum-magnesium alloy, silver, or silver-magnesium alloy. The material of the first electrode (the anode) of the present invention can be any conventional material for electrodes. Preferably, the material of the first electrode is a transparent electrode material. More preferably, the material of the second electrode is InSnO₃, indium tin oxide (ITO), aluminum zinc oxide (AZO), indium zinc oxide (IZO), SnO₂, ZnO-doped In₂O₃, CdSnO, or antimony. The materials of the source and the drain can be any conventional electrode material. Preferably, the materials of the source and the drain are the same. More preferably, the materials of the source and the drain are low temperature polysilicon. The organic electroluminescent medium of the present invention can be any conventional organic function material. Preferably, the organic electroluminescent medium comprises an electron injecting layer, an electron transporting layer, an organic electroluminescent layer, a hole transporting layer, a hole injecting layer, and the combinations thereof that is located between the second electrode (the cathode) and the first electrode (the anode). It is preferred to dispose a dielectric passivation layer between the conductive lines. The dielectric passivation layer can be made of any conventional passivation material. Preferably, the dielectric passivation layer is made of polyimide, acrylic resins, fluoric resins, epoxy resins, silicon oxide, silicon nitride, or silicon oxynitride. The arrangement of the gate, the source, and the drain of the transistor of the present invention can be any conventional style. Preferably, the transistor is a staggered thin film transistor (TFT), an inverted staggered TFT, a coplanar TFT, or an inverted coplanar TFT. It is optional to dispose a buffer layer over the surface of the substrate of the present invention in order to shield off the moisture, oxygen, or ions. The material of the buffer layer can be any conventional isolating material that isolates the moisture, oxygen, or ions in the air. Preferably, the material of the buffer layer is silicon nitride, silicon oxide, or silicon oxynitride. The method for forming the silicon layer of the method for manufacturing an active matrix organic electroluminescent panel of the present invention can be any conventional thin film deposition method. Preferably, the silicon layer is formed by chemical vapor deposition. The method for patterning the source, the drain, the lightly doped drain (LDD), and the channel can be any conventional method. Preferably, the source, the drain, the lightly doped drain (LDD), and the channel are patterned by photolithography and ion doping. More preferably, the source, the drain, the lightly-doped drain (LDD), and the channel are patterned by photolithography and ion doping, and then annealed and activated by excimer laser. The method for manufacturing an active matrix organic electroluminescent panel of the present invention preferably comprises a step of forming a patterned insulating layer over the functional element that has a source and a drain, and a step of forming a patterned gate layer over the insulating layer.

Preferably, the active matrix organic electroluminescent panel of the present invention has a plurality of red, green, and blue pixel arrays for displaying the image. Also, it is optional for the organic electroluminescent panel of the present invention to have a monochrome pixel array.

The aforesaid organic electroluminescent panel can be applied to any purpose or apparatus for displaying images, graphics, characters and texts; and preferably, to televisions, computers, information display devices of printers, monitors, information display devices of vehicles, the displays of signal machines, information display devices of communication apparatus (such as cell phones, telephones), information display devices of telephones, interactive electronic books, micro-displays, displays of fishing devices, personal digital assistants (PDAs), virtual reality game means, information display devices of simulative flying training, displays of airplane equipment, and displays of visors for video games.

Other achievements, advantages, and novel features of the invention will become more apparent from the following detailed description when taken in conjunction with the accompanying drawings.

### BRIEF DESCRIPTION OF THE DRAWINGS

FIG. 1 is a cross sectional view showing the functional element and the pixel of the active matrix organic electroluminescent panel of the present invention;

FIG. 2 is a perspective view showing the active matrix organic electroluminescent panel of the present invention;

FIG. 3 is a top view showing the pixel display unit array of the active matrix organic electroluminescent panel of the present invention; and

FIG. 4 is a circuit diagram showing the circuit of the pixel display unit of the active matrix organic electroluminescent panel of the present invention.

### DETAILED DESCRIPTION OF THE PREFERRED EMBODIMENT

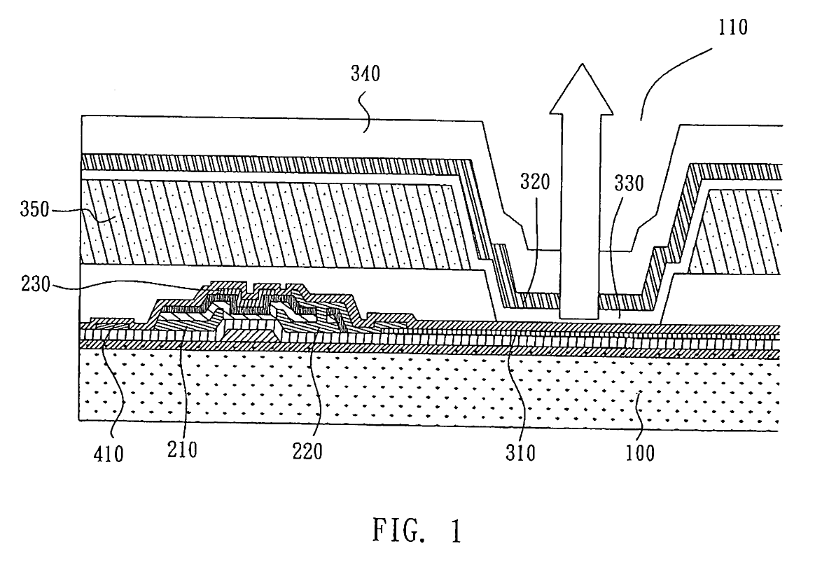

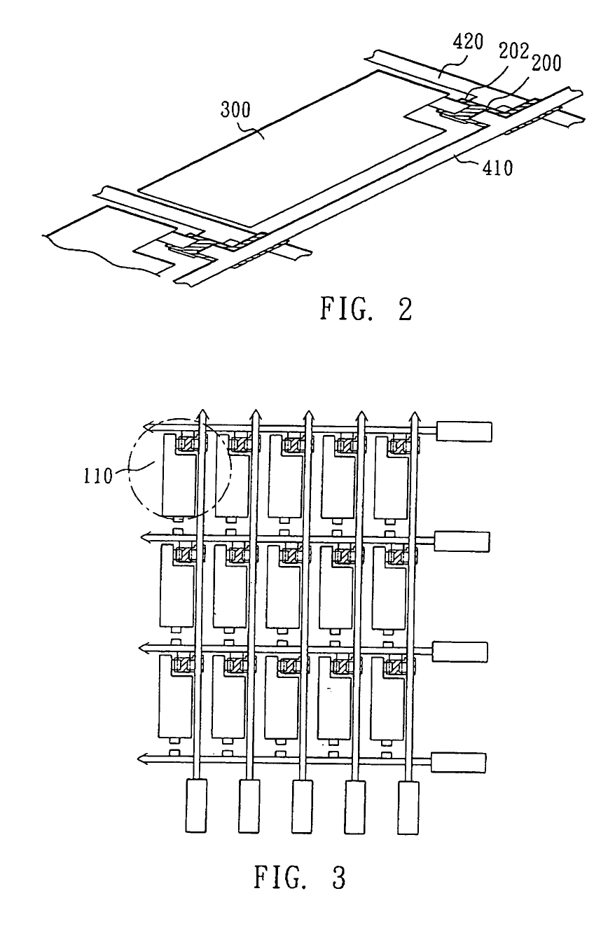

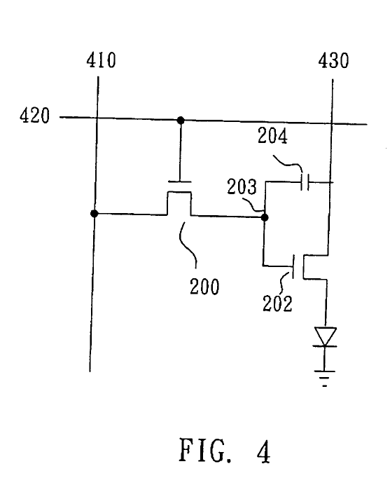

With reference to FIGS. 1-4, the active matrix organic electroluminescent panel of the present invention comprises a plurality of pixel display units 110 over a substrate 100. The pixel display unit 110 has at least one transistor. In the present embodiment, the pixel display unit 110 has two transistors and a display device 300. The two transistors are a switch transistor 200 and a driving transistor 202. The transistors 200, 202 has a source 210, a gate 230, and a drain 220. In the present preferred embodiment, the transistors 200,202 are formed by the CMOS process that utilizes photolithography and ion doping. In particular, the source 210 and the drain 220 are formed by a low temperature polysilicon process and excimer laser annealing and activation. The transistors 200, 202 are well arranged in order to provide a stable current for driving the display device 300. The display device300 at least comprises two electrode layers and an organic electroluminescent medium 330 disposed over the substrate 100, wherein a second electrode layer (cathode layer) 310 is disposed over the surface of the substrate 100, a first electrode layer (anode layer) 320 is disposed above the cathode layer 310, and the organic electroluminescent medium 330 is sandwiched between the cathode layer 310 and the anode layer 320. In the embodiment of the present invention, the cathode layer 310 is made of aluminum, aluminum-magnesium alloy, silver, silver-copper alloy, or silver-magnesium alloy; and the anode layer 320 is made of transparent indium tin oxide (ITO), indium zinc oxide (IZO), or aluminum zinc oxide (AZO). The cathode layer 310 of the display device 300 connects to the drain of the transistor 202 so that a sufficient current is provided to drive and make the organic electroluminescent medium 330 luminesce when the current flows from the source 210 to the drain 220.

There is a plurality of conductive lines disposed between the pixel display units 110 over the substrate 100. The conductive lines can be classified into two to four groups, i.e. the source conductive line, the gate conductive line, the power conductive line, and the cathode conductive line. In the present preferred embodiment, the conductive lines are classified into three groups. The first group is composed of the source conductive lines 410. In the present preferred embodiment, the source conductive lines 410 are plural straight and parallel conductive lines. The first group of conductive lines connects to the source 210 of the transistor 200 for transmitting display signals. In the present embodiment, the first group of conductive lines is made of silver-copper alloy. The silver-copper alloy that is suitable for use in the embodiment of the present invention comprises 80 to 99.8 mol % of silver, 0.1 to 10 mol % of copper, and 0.1 to 10 mol % of at least one transition metal selected from the group consisting of palladium, magnesium, gold, platinum, and the combinations thereof, wherein the total mol % of the silver-copper alloy is 100. The silver-copper alloy of the present invention optionally has at least one adhesion improver for improving the adhesion of the silver-copper alloy to the substrate. Preferably, the adhesion improver is composed of 0.01 to 5 mol % of titanium, aluminum, nickel, cobalt, or chromium.

The second group of conductive lines is composed of gate conductive lines 420. In the preferred embodiment, the gate conductive lines 420 are straight and parallel. The conductive lines of the second group connects to the gate 230 of the transistor 200 of the pixel display unit 110 for transmitting signals. Similarly, the conductive lines of the second group are made of silver-copper alloy, which has the same composition as that alloy of the conductive lines of the first group.

The conductive lines of the third group are power conductive lines 430, which are disposed respectively between the parallel conductive lines 410 of the first group. The power conductive lines 430 provide current to the transistor 202 so that a stable current is supplied to the anode as the channel of the transistor 202 is opened. In the present embodiment, the conductive lines 430 are parallel and straight. The power conductive lines 430 connect to the source 210 of the transistors 202 of the pixel display units 110 for transmitting signals. Similarly, the conductive lines of the third group are made of silver-copper alloy, which has the same composition as the alloy of the conductive lines of the first group.

In the present embodiment, the scan signals are inputted to the pixel through the gate conductive lines 420 to turn on the switch transistor 200, and then the data signals are transmitted from the source to the drain of the switch transistor 200. Subsequently, the connecting conductive lines 203 provide a voltage that is higher than the threshold voltage of the driving transistor 202 to the gate of the driving transistor 202 for conducting the source and the drain of the driving transistor 202. On the other hand, the capacitor 204 that connects the connecting conductive line 203 and is charged by the power conductive line 430 and then provides the driving transistor 202 a stable voltage so that a stable driving current is supplied to the first electrode (the anode) for make the organic electroluminescent medium luminesce. In the present embodiment, the connecting conductive lines 203 are made of silver-copper alloy, which has the same composition as the alloy of the conductive lines of the first group.

The method for manufacturing an organic electroluminescent panel of the present invention first forms an amorphous silicon layer over the substrate 100. In the present embodiment, the amorphous silicon layer is formed over a glass substrate by chemical vapor deposition. Afterwards, the source of the transistor 200 is formed over the amorphous silicon layer by the CMOS process, which comprises the steps of patterning by photolithography, such as sputtering or evaporation, coating the photoresist, exposure, developing, and etching; impurity doping or ion implantation; and annealing by excimer laser. As a result, the amorphous silicon is transferred into crystalline silicon and the impurity is activated. The CMOS process is repeated to form the drain and the lightly doped drain. Next, the gate layer is formed by sputtering and then patterned to form the gate and the gate conductive line (the second conductive line) by photolithography. Afterwards, the source conductive layer and the cathode layer are deposited by sputtering and patterned to form the source conductive line 410 and the cathode electrode 310 by photolithography. The materials of the source conductive line 410 and the cathode electrode 310 can be the same or different. In the present embodiment, both the materials of the source conductive line 410 and the cathode layer 310 are silver-copper alloy. The source conductive line 410 connects to the source 210 or the drain 220, and the gate conductive line 420 connects to the gate 230. Consequently, a plurality of transistors having the gate 230, the source 210, and the drain 220 is formed over the substrate, as well as the display device 300, the source conductive line 410, the gate conductive line 420, and the power conductive line 430.

Afterwards, an adhesion interface and a passivation layer are deposited over the substrate. The passivation layer is then patterned to form the passivation layer 340 outside the predetermined location of the pixel display unit. Next, the organic electroluminescent device is formed on the cathode of the pixel display unit. For example, a hole injecting layer, a hole transporting layer, an organic electroluminescent medium, an electron transporting layer, and an electron injecting layer are formed by evaporation in the present embodiment. After the organic electroluminescent medium is formed, an anode layer is formed on the organic electroluminescent medium by sputtering or evaporation. In the present embodiment, the anode layer is made of indium tin oxide.

The organic electroluminescent panel of the present invention uses a distinctive conductive material (the silver-copper alloy) to form the conductive lines, such as the power conductive lines, the second conductive lines, and the connecting conductive lines so that the resistance of the conductive lines of the panel is effectively reduced. Also, the adhesion of the conductive lines is improved. Besides, the formation of hillock, the oxidation of surface, occurrence of the parasitic capacitor, and the formation of pinhole are successfully prevented. Because the silver-copper alloy is less active, the reliability of the device can be improved. Moreover, the RC-delay is reduced owing to the low resistance of the silver-copper alloy. On the other hand, the organic electroluminescent panel of the present invention uses a distinctive conductive material (the silver-copper alloy) to form the conductive lines, such as the power conductive lines, the second conductive lines, and the connecting conductive lines, so the organic electroluminescent panel can be manufactured by only using the conventional deposition and photolithography processes, which are easy and rich in back-up resources. Being compared with those prior arts aforesaid, the manufacture and production of the present invention are convenient, trouble-free and cost-effective.

Although the present invention has been explained in relation to its preferred embodiment, it is to be understood that many other possible modifications and variations can be made without departing from the spirit and scope of the invention as hereinafter claimed.

What is claimed is:

1. An active matrix organic electroluminescent panel, comprising:
a substrate;
a plurality of functional elements located over the substrate;
a plurality of organic electroluminescent devices disposed over the substrate; wherein the organic electroluminescent device comprised, in sequence, a first electrode, at least one organic electroluminescent media and a second electrode; and
a plurality of conductive lines disposed over the surface of the substrate to connect the and/or organic electroluminescent devices;
wherein
the conductive lines comprise silver-copper alloy.

2. The active matrix organic electroluminescent panel as claimed in claim 1, wherein the silver-copper alloy comprises 80 to 99.8 mol % of silver, 0.1 to 10 mol % of copper, and 0.1 to 10 mol % of transition metal selected from the group consisting of palladium, magnesium, gold, platinum, and the combinations thereof, and the total mol % of the silver-copper alloy is 100.

3. The active matrix organic electroluminescent panel as claimed in claim 1, wherein the silver-copper alloy further comprises at least one adhesion improver selected from the group consisting of titanium, aluminum, nickel, cobalt, and chromium.

4. The active matrix organic electroluminescent panel as claimed in claim 3, wherein the mole percentage of the adhesion improver ranges from 0.01 to 5.

5. The active matrix organic electroluminescent panel as claimed in claim 1 further comprising a buffer layer disposed over the surface of the substrate.

6. The active matrix organic electroluminescent panel as claimed in claim 5, wherein the buffer layer is made of silicon nitrides, silicon oxides, or silicon oxynitride.

7. The active matrix organic electroluminescent panel as claimed in claim 1, wherein the second electrode is made of aluminum, silver, aluminum-magnesium alloy, or silver-magnesium alloy.

8. The active matrix organic electroluminescent panel as claimed in claim 1, wherein the organic electroluminescent medium comprises an electron injecting layer, an electron transporting layer, an organic electroluminescent layer, a hole transporting layer, a hole injecting layer, and the combinations thereof located between the second electrode and the first electrode.

9. The active matrix organic electroluminescent panel as claimed in claim 1, wherein the first electrode is a transparent electrode.

10. The active matrix organic electroluminescent panel as claimed in claim 1, wherein the first electrode is made of InSnO₃, indium tin oxide (ITO), aluminum zinc oxide (AZO), indium zinc oxide (IZO), SnO₂, ZnO-doped In₂O₃, CdSnO, or antimony.

11. The active matrix organic electroluminescent panel as claimed in claim 1, wherein there is at least one dielectric passivation layer disposed between the conductive lines.

12. The active matrix organic electroluminescent panel as claimed in claim 11, wherein the dielectric passivation layer is made of polyimide, acrylic resins, fluoric resins, epoxy resins, silicon oxide, silicon nitride, or silicon oxynitride.

13. The active matrix organic electroluminescent panel as claimed in claim 1, wherein the functional element is a transistor comprising a source, a gate and a drain having staggered, inverted staggered, coplanar, or inverted coplanar arrangement.

14. The active matrix organic electroluminescent panel as claimed in claim 13, wherein the gate and/or the drain are made of polysilicon.

15. The active matrix organic electroluminescent panel as claimed in claim 1, wherein the functional element comprises a capacitor.

16. The active matrix organic electroluminescent panel as claimed in claim 1, wherein the functional element comprises two sets of drains, sources and gates, and a capacitor.

17. The active matrix organic electroluminescent panel as claimed in claim 1 further comprising a connecting conductive line, which connects the functional elements and comprises the silver-copper alloy.

18. The active matrix organic electroluminescent panel as claimed in claim 1, further comprising at least an insulating layer.

19. The active matrix organic electroluminescent panel as claimed in claim 1, wherein the substrate is a glass substrate, a plastic substrate, or a transparent resin plate.

20. The active matrix organic electroluminescent panel as claimed in claim 1, wherein the substrate is made of polycarbonate, polyethylene terephthalate (PET), cyclic olefin copolymer (COC), or metal-containing cyclic olefin copolymer (m-COC).

21. The active matrix organic electroluminescent panel as claimed in claim 1, wherein conductive line is power conducting line, gate conducting line and/or source conducting line.
